(19) United States
(12) Patent Application Publication
(10) Pub. No.: US 2020/0176712 A1
(43) Pub. Date: Jun. 4, 2020

(54) FLEXIBLE DISPLAY, PRODUCTION METHOD THEREFOR, AND FLEXIBLE DISPLAY SUPPORT SUBSTRATE

(71) Applicant: SAKAI DISPLAY PRODUCTS CORPORATION, Sakai-shi, Osaka (JP)

(72) Inventors: KOHICHI TANAKA, Sakai-shi, Osaka (JP); KATSUHIKO KISHIMOTO, Sakai-shi, Osaka (JP)

(21) Appl. No.: 16/615,125

(22) PCT Filed: Jun. 27, 2017
(86) PCT No.: PCT/JP2017/023517

§ 371 Date: Jan. 30, 2020

(51) Int. Cl. H01L 51/52; H01L 51/00; H01L 51/56

(52) U.S. Cl. CPC H01L 51/5253; H01L 2251/5338; H01L 51/56; H01L 51/0097

(57) ABSTRACT

A flexible display supporting substrate (10) of the present disclosure includes: a glass base (11); a plastic film (12) which has a surface (12s), the plastic film being supported by the glass base (11); and a sintered layer (20) covering the surface (12s) of the plastic film (12).

### TECHNICAL FIELD

The present disclosure relates to a flexible display and a production method thereof, and a flexible display support substrate.

### BACKGROUND ART

A typical example of the flexible display includes a film which is made of a synthetic resin such as polyimide (hereinafter, referred to as “plastic film”), and elements supported by the plastic film, such as TFTs (Thin Film Transistors) and OLEDs (Organic Light Emitting Diodes). The plastic film functions as a flexible substrate. The flexible display is encapsulated with a gas barrier film (encapsulation film) because an organic semiconductor layer which is a constituent of the OLED is likely to deteriorate due to water vapor.

Production of the above-described flexible display is carried out using a glass base on which a plastic film is formed over the upper surface (flexible display supporting substrate). The glass base functions as a support for keeping the shape of the plastic film flat during the production process. Elements such as TFTs and OLEDs, a gas barrier film, and the other constituents are formed on the plastic film, whereby the structure of a flexible device is realized while it is supported by the glass base. Thereafter, the flexible device is separated from the glass base and gains flexibility. The entirety of a portion in which elements such as TFTs and OLEDs are arrayed is also referred to as “functional layer”.

A foreign substance such as particles (hereinafter, also referred to as “contamination”) is likely to adhere to the surface of a plastic film supported by a glass base. The contamination can deteriorate the device characteristics and the gas barrier film. A particle whose diameter is greater than, for example, 0.5 μm (typically, a particle which has a height of 1 μm to 3 μm) can be a cause of defects in TFTs, a cause of short-circuit or breakage of wires in the functional layer, or a cause of formation of a leak path for water vapor in the gas barrier film.

Patent Document No. 1 discloses a minute protrusion polishing apparatus for polishing away minute protruding portions on a flat plate by bringing a polishing tape into contact with the minute protruding portions. When such a protrusion polishing apparatus is used, particles can be removed by polishing.

Patent Document No. 2 discloses the technique of applying a mixture prepared by dissolving an insulative material in a solvent from the tip of a needle to defective portions such as a foreign substance on a pixel electrode and raised and recessed portions so as to cover these defective portions. The mixture is in the form of a liquid when it is applied. By subsequent heating, the mixture changes into a solidified insulating film. The insulating film that covers the defective portions suppresses occurrence of an abnormal electric current which is attributed to the defective portions.

### CITATION LIST

### Patent Literature

Patent Document No. Japanese Laid-Open Patent Publication No. 2008-213049

Patent Document No. 2: WO 2013/190841

### SUMMARY OF INVENTION

### Technical Problem

By detecting a particle on the substrate and selectively polishing the particle using a polishing apparatus such as disclosed in Patent Document No. 1, the smoothness of the substrate surface is improved. However, according to research by the present inventors, it was found that if a gas barrier film and devices such as TFTs and OLEDs are formed on such a substrate, there is a probability that sufficient encapsulation performance cannot be realized.

According to the technique disclosed in Patent Document No. 2, the insulation of the defective portions improves, but the height of raised portions such as particles is not reduced and, therefore, the smoothness of the surface is not sufficiently improved. Thus, it is estimated that if the technique disclosed in Patent Document No. 2 is applied to production of a flexible display, the encapsulation performance deteriorates due to raised portions such as particles.

The present disclosure provides a flexible display and a production method thereof, and a flexible display supporting substrate, which can solve the above-described problems.

### Solution to Problem

A flexible display of the present disclosure includes, in an exemplary embodiment, a flexible substrate; an OLED device supported by the flexible substrate; a first gas barrier film covering the flexible substrate, the first gas barrier film being located between the OLED device and the flexible substrate; and a second gas barrier film supported by the flexible substrate and covering the OLED device. The flexible substrate includes a plastic film which has a front surface and a rear surface flatter than the front surface, and a sintered layer covering the front surface of the plastic film.

In one embodiment, the front surface of the plastic film has a protrusion whose height is not less than 50 nm and not more than 300 nm and/or a recessed portion whose depth is not less than 50 nm and not more than 300 nm.

In one embodiment, the thickness of the sintered layer is not less than 100 nm and not more than 500 nm.

In one embodiment, the sintered layer has an upper surface flatter than the front surface of the plastic film.

In one embodiment, the plastic film is made of biphenyl type polyimide.

A flexible display supporting substrate of the present disclosure includes, in an exemplary embodiment, a glass base; a plastic film which has a surface, the plastic film being supported by the glass base; and a sintered layer covering the surface of the plastic film.

In one embodiment, the sintered layer has an upper surface flatter than the surface of the plastic film.

In one embodiment, the flexible display supporting substrate includes a gas barrier film covering the sintered layer.

A flexible display production method of the present disclosure includes, in an exemplary embodiment, providing a flexible display supporting substrate which includes a glass base and a plastic film on the glass base; forming a sintered layer so as to cover a surface of the plastic film; forming a first gas barrier film so as to cover a surface of the sintered layer; forming an OLED device so as to be supported by the flexible substrate; and forming a second gas barrier film so as to be supported by the flexible substrate and so as to cover the OLED device.

In one embodiment, forming the sintered layer includes supplying a liquid material to the surface of the plastic film, and forming the sintered layer or the liquid material by heating the liquid material.

In one embodiment, the liquid material is a sol which contains an alkoxide.

In one embodiment, forming the sintered layer includes heating the liquid material to 350° C. or higher.

In one embodiment, the method further includes forming on the sintered layer a gas barrier film having a thickness of not less than 200 nm and not more than 1,000 nm.

In one embodiment, the method further includes, before supplying a liquid material to the surface of the plastic film, polishing a part of a surface of the plastic film, thereby forming a recessed portion in the surface.

In one embodiment, the plastic film is made of polyimide, and the pH of the liquid material is not more than 10.

### Advantageous Effects of Invention

According to an embodiment of the present invention, deterioration of the encapsulation performance of a flexible display which is attributed to minute structures over the substrate surface before formation of a gas barrier film can be suppressed.

### BRIEF DESCRIPTION OF DRAWINGS

FIG. 1 is a diagram showing a cross section of a part of a typical example of a flexible display supporting substrate.

FIG. 2 is a cross-sectional view of a flexible display supporting substrate of a conventional example.

FIG. 3 is a cross-sectional view of a structure in which a gas barrier film is provided on a flexible display supporting substrate of a conventional example.

FIG. 4A is a cross-sectional view illustrating a step of a flexible display production method in an embodiment of the present disclosure.

FIG. 4B is a cross-sectional view illustrating a seep of the production method in an embodiment of the present disclosure.

FIG. 4C is a cross-sectional view illustrating a step of the production method in an embodiment of the present disclosure.

FIG. 4D is a cross-sectional view illustrating a step of the production method in an embodiment of the present disclosure.

FIG. 5A is a cross-sectional view illustrating a step of the production method in an embodiment of the present disclosure.

FIG. 5B is a cross-sectional view illustrating a step of the production method in an embodiment of the present disclosure.

FIG. 5C is a cross-sectional view illustrating a step of the production method in an embodiment of the present disclosure.

FIG. 5D is a cross-sectional view of a flexible display in an embodiment of the present disclosure.

FIG. 6 is an equivalent circuit diagram of a single sub-pixel in a flexible display.

FIG. 7 is a perspective view of a flexible display supporting substrate in the middle of the production process.

### DESCRIPTION OF EMBODIMENTS

<Inventors' Knowledge>

Before an embodiment of the present invention is described, the knowledge found by the present inventors is described.

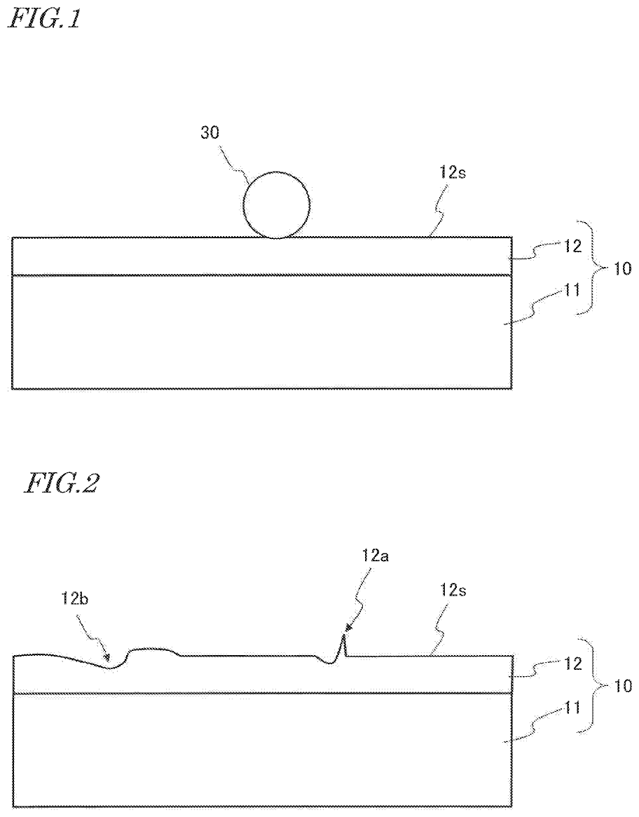

FIG. 1 is a diagram showing a cross section of a part of a typical example of a flexible display supporting substrate (hereinafter, simply referred to as “supporting substrate”) 10. The supporting substrate 10 of FIG. 1 includes a glass base 11 and a plastic film 12 provided on the glass base 11. Usually, the glass base is referred to as glass substrate. In this example, the plastic film 12 is a polyimide film, and there is a particle 30 adhered to a surface 12s of the plastic film 12. The diameter or height of the particle 30 can be, for example, several micrometers.

Although the shown particle 30 is spherical, actual particles 30 can have various shapes. If the diameter or height of the particle 30 is for example greater than 0.5 μm, as previously described, there is a probability that the characteristics of a device supported by the supporting substrate 10 and the gas barrier film will deteriorate. Therefore, removing the particle 30 before formation of the device and the gas barrier film is preferred. The particle 30 is an irregular structure which can be detected by external observation. Removal of the particle 30 can be realized by a local planarization process with the use of the previously-described polishing apparatus.

According to research by the present inventors, even when the planarization process is carried out using the polishing apparatus, the moisture resistance of the flexible display can deteriorate. The present inventors found that microscopic irregularities on a scale different from the irregular structure oft such a size which can be detected by external observation are formed in the surface 12s of the plastic film 12. Such irregularities can be formed when the plastic film 12 comes into contact with a transporting unit during transportation of the supporting substrate 10 or when a planarization process of the plastic film 12 is carried out using the polishing apparatus.

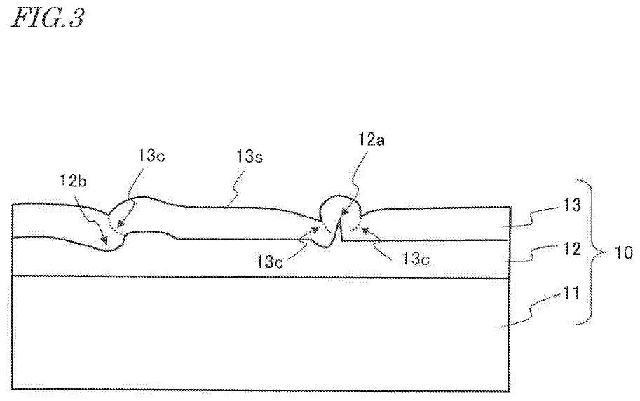

FIG. 2 is a schematic cross-sectional view drawn based on a cross-sectional electron microscope image of the supporting substrate 10. In FIG. 2, the surface 12s of the plastic film 12 has a protrusion 12a whose height is not less than 50 nm and not more than 300 nm and a recessed portion 12b whose depth is not less than 50 nm and not more than 300 nm. Irregularities of such sizes can be detected by microscopic observation of a cross section but are difficult to detect by nondestructive observation of the surface 12s of the plastic film 12 from the outside. The present inventors conclude that such minute irregularities can be a cause of deterioration in moisture resistance performance and this was not known before now because of the following reasons.

In the first place, such minute irregularities could not be detected by nondestructive observation of the surface 12s of the plastic film 12 from the outside (typically, observation with an optical microscope). Therefore, when foreign substances or steps which can cause defects are not detected but the moisture resistance performance deteriorated, it was estimated that a pinhole defect in the gas barrier film is a cause of deterioration in moisture resistance performance. This is because of an opinion that such a pinhole defect can inevitably occur in forming the gas barrier film even if the underlayer is flat. However, there was another opinion that, when the gas barrier film is formed by chemical vapor deposition (CVD), the probability of formation of a pinhole defect in the gas barrier film in the absence of foreign substances such as particles in the underlayer is low. Although details of the causes of deterioration in moisture resistance performance are not fully elucidated, the results of microscopic observation by the present inventors clear up one of the causes of deterioration in moisture resistance performance.

As will be described later, according to an embodiment of the present disclosure, even if the surface 12s of the plastic film 12 has a protrusion 12a whose height is not less than 50 nm and not more than 300 nm and/or a recessed portion 12b whose depth is not less than 50 nm and not more than 300 nm, deterioration in moisture resistance performance can be suppressed without the step of detecting and removing all of such irregularities. Thus, the embodiment of the present disclosure can bring about particularly excellent effects when any of the surfaces of the plastic film has minute irregularities which, in the prior art, could cause deterioration in moisture resistance performance while the causes are not identified.

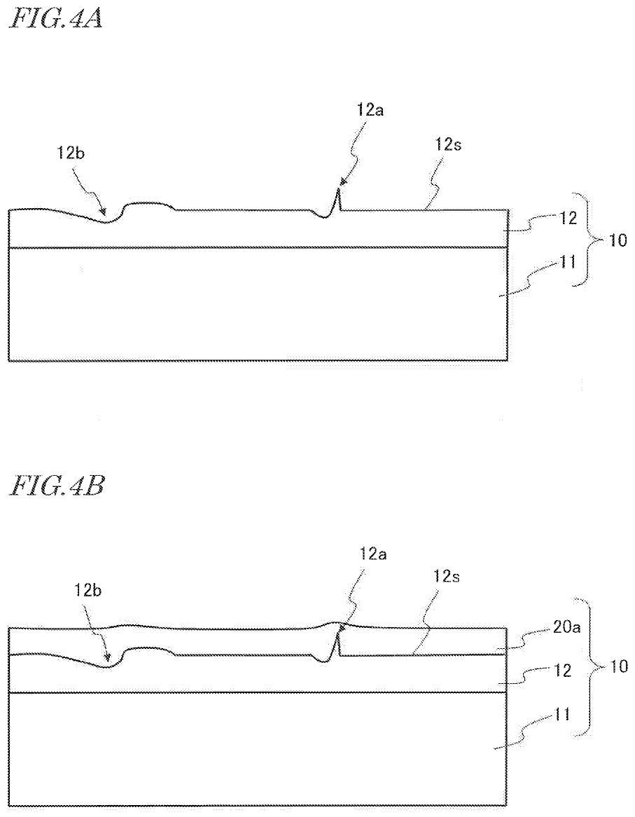

FIG. 3 is a diagram schematically showing a cross section of a structure where a gas barrier film 13 of about 1000 nm in thickness, which was realized by a silicon nitride film (SiN film), was provided on the supporting substrate 10 that had the configuration of FIG. 2. In this example, the gas barrier film 13 was deposited by CVD on the plastic film 12. In the gas barrier film 13, a plurality of cracks 13c occurred which were attributed to the minute protrusion 12a and the recessed portion 12b in the surface 12s of the plastic film 12 that is the underlayer. Such cracks 13c can deteriorate the moisture resistance performance of the gas barrier film 13.

The present inventors carried out an attempt to cover the surface 12s of the plastic film 12 with a film for planarization (planarization film) before deposition of the gas barrier film 13. However, when the planarization film was formed by physical vapor deposition such as sputtering or CVD, sufficient planarization was not achieved if the thickness was about 500 nm or smaller, and the moisture resistance performance of the gas barrier film 13 did not improve to a practical level. In a planarization film deposited by sputtering or CVD, the probability is high that abrupt irregularities resulting from minute protrusions 12a such as shown in FIG. 2 cannot be sufficiently moderated.

### Embodiment

Hereinafter, an embodiment of the present disclosure is described. In the present embodiment, a sintered layer is formed of a liquid material by a sol-gel method, and this sintered layer covers the entirety of the surface of the plastic film. In the following description, unnecessarily detailed description will be omitted. For example, detailed description of well-known matter and repetitive description of substantially identical elements will be omitted. This is for the purpose of avoiding the following description from being unnecessarily redundant and assisting those skilled in the art to easily understand the description. The present inventors provide the attached drawings and the following description for the purpose of assisting those skilled in the art to fully understand the present disclosure. Providing these drawings and description does not intend to limit the subject matter recited in the claims.

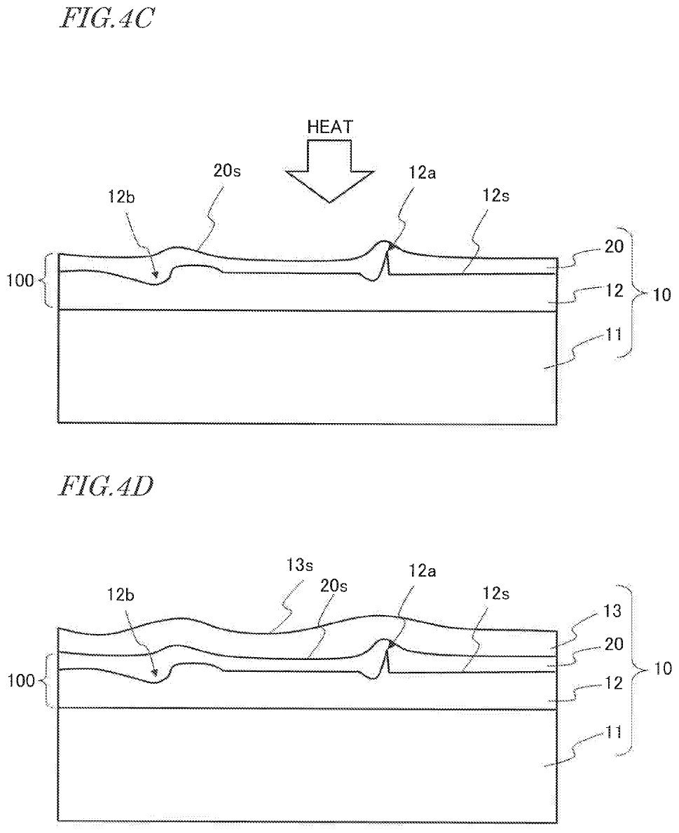

First, refer to FIG. 4A. FIG. 4A shows a cross section of a part of the flexible display supporting substrate 10 in the initial phase of the production process of the flexible display. The supporting substrate 10 includes a glass base 11 and a plastic film 12 provided on the glass base 11. The surface 12a of the plastic film 12 shown in the drawing has the above-described minute protrusions 12a and recessed portions 12b.

The glass base 11 is a supporting substrate for processes. The thickness of the glass base 11 can be, for example, about 0.3-0.7 mm.

In the present embodiment, the plastic film 12 is a polyimide film having a thickness of, for example, not less than 5 μm and not more than 100 μm. The polyimide film can be formed from a polyamide acid, which is a precursor of polyimide, or a polyimide solution. The polyimide film may be formed by forming a polyamide acid film on the surface 12s of the glass base 11 and then thermally imidizing the polyamide acid film. Alternatively, the polyimide film may be formed by forming, on the surface 12s of the glass base 11, a film from a polyimide solution which is prepared by melting a polyimide or dissolving a polyimide in an organic solvent. The polyimide solution can be obtained by dissolving a known polyimide in an arbitrary organic solvent. The polyimide solution is applied to the surface 12s of the glass base 11 and then cried, whereby a polyimide film can be formed.

In the case of a bottom emission type flexible display, it is preferred that the polyimide film realizes high transmittance over the entire range of visible light. The transparency of the polyimide film can be represented by, for example, the total light transmittance in accordance with JIS K7105-1981. The total light transmittance can be set to not less than 80% or not less than 85%.

The plastic film 12 is to be in contact with an alkaline liquid material in subsequent steps. Thus, it is preferred that the plastic film 12.s made of biphenyl type polyimide, which has excellent alkaline resistance. The biphenyl type polyimide has a carbonyl group of an imide bond which is adjacent to a biphenyl structure. This carbonyl group is unlikely to undergo hydrolysis with an alkaline material as compared with a carbonyl group of an imide bond which is adjacent to a monocyclic benzene ring.

The plastic film 12 may be a film which is made of a synthetic resin other than polyimide. Note that, however, in the embodiment of the present disclosure, when the sintered layer is formed by a sol-gel method, a heat treatment at not less than 350° C. is typically performed, and therefore, the plastic film 12 is made of a material which will not be deteriorated by this heat treatment.

The plastic film 12 may be a multilayer structure including a plurality of synthetic resin layers. In the present embodiment, in delaminating a flexible display structure from the glass base 11, laser lift-off is carried out such that the plastic film 12 is irradiated with ultraviolet laser light transmitted through the glass base 11. The plastic film 12 may include a sacrificial layer which is to absorb such ultraviolet laser and decompose. The sacrificial layer may be provided on a side of the plastic film 12 which is in contact with the glass base 11.

Next, as shown in FIG. 4B, a liquid material 20a is supplied to the surface 12s of the plastic film 12 such that a layer of the liquid material 20a covers the surface 12s of the plastic film 12. A typical example of the liquid material 20a is a sol which contains an alkoxide.

A typical example of the alkoxide is a metal alkoxide. An example of the metal element contained in the metal alkoxide can be a transition metal, a rare earth metal, or a metal element of Group 3 to Group 5 and Group 13 to Group 15. A typical example is one or more metal elements selected from the group consisting of Si, Ti, Ta and Ai. Note that, strictly, Si is an element which is a constituent of a semiconductor, although in the present specification Si is included in the metal elements for the sake of convenience.

Examples of the alkoxy group contained in the metal alkoxide include methoxy group, ethoxy group, propoxy group, isopropoxy group, butoxy group, isobutoxy group, pentyloxy group, and hexyloxy group. The metal alkoxide may contain a hydrocarbon group, such as alkyl group, cycloalkyl group, aryl group, and aralkyl group.

The metal alkoxide can be expressed by formula (1):

(R1)ₘM(OR2)_{X-m} (1)

where R1 is an alkyl group, a cycloalkyl group, an aryl group, or an aralkyl group. R1 may have a substituent. R2 is a lower alkyl group. R1 and R2 may differ depending on m. M is a metal element whose valence is not less than 3. X is the valence of the metal M. m is an integer from 0 to 2 and satisfies the relationship of X−m≥2.

The liquid material 20a may contain metal alkoxides of the same type or different types or may contain other additives.

The liquid material 20a contains an organic solvent as a constituent. Examples of the organic solvent include alcohols, aromatic hydrocarbons, ethers, nitrogen-containing solvents, sulfoxides, and mixture solvents thereof. A solvent-soluble polymer can also be used as the organic solvent.

The liquid material 20a may contain a hardening catalyst. Examples of the hardening catalyst include ternary amines and acid catalysts. The liquid material 20a may contain various additives, such as plasticizer, antioxidant, ultraviolet absorber, flame retardant, antistatic agent, surfactant, filler, colorant, etc.

The liquid material 20a can be prepared by adding a solvent-soluble polymer, a hardening catalyst, an organic solvent, and other constituents to a metal alkoxide or a hydrolyzed metal alkoxide and kneading the resultant mixture. If the metal alkoxide exhibits strong alkalinity, there is a probability that the metal alkoxide will deteriorate the plastic film 12. Thus, when the plastic film 12 is made of a common polyimide, it is preferred that the pH of the liquid material 20a is not more than 10. The pH of the liquid material 20a can be typically set in the range of, for example, not less than 3.5 and not more than 9.0. The liquid material 20a can be supplied to the surface 12s of the plastic film 12 by various methods such as, for example, spin coating, dip coating, slit coating, etc. The film of the liquid material 20a covering the surface 12s of the plastic film 12 is dried by heating and thereafter subjected to a heat treatment for sintering.

The liquid material 20a has fluidity unlike a solid film deposited by physical vapor deposition, such as sputtering, or CVD. The liquid material 20a spreads over the entirety of the surface 12a of the plastic film 12 due to surface tension. Thus, the liquid material 20a is excellent in step coverage. Even if a relatively thin film of the liquid material 20a which has a thickness of not more than 300 nm is formed, a surface of high flatness is obtained. The liquid material 20a can tightly adhere to the surface of the protrusion 12a of the plastic film 12 due to surface tension even if the protrusion 12a of the plastic film 12 is minute. Even if the recessed portion 12b of the plastic film 12 is locally deeper, the liquid material. 20a reaches the deeper portion and can fill the inside of the recessed portion 12b.

In the case of using a dip coating method or the like, the viscosity of the liquid material 20a can be set in the range of, for example, not less than 25 mPa·s and not more than 200 mPa·s. In the case of using an application method such as slit coating, the viscosity of the liquid material 20a car be set in the range of, for example, not less than 100 mPa·s and not more than 2000 mPa·s. The thickness of the layer of the liquid material 20a covering the surface 12s of the plastic film 12 is in the range of, for example, not less than 100 nm and not more than 1000 nm. The thickness of the layer of the liquid material 20a can be controlled by adjusting the amount of the liquid material 20a supplied to the surface 128 of the plastic film 12. In the case of spin coating, for example, the amount of the supplied liquid material 20a can be adjusted by the viscosity and the spinning speed.

Before the liquid material 20a is supplied to the surface 12s of the plastic film 12, the surface 12s of the plastic film 12 may be partially polished away. This polishing may be selectively carried out at a position where a particle 30 such as shown in FIG. 1 is detected rather than being carried out on the surface 12s of the plastic film 12.

Detection of the particle 30 can be realized by, for example, processing an image obtained by an image sensor. The size of the particle 30 can be relatively accurately measured in a direction parallel to the surface 12s of the plastic film 12. However, it is difficult to accurately determine the size in a direction perpendicular to the surface 12s, i.e., the height, of the particle 30. Therefore, determination of the polishing amount is desirably carried out with a sufficient margin such that an unpolished portion does not occur. Excessive polishing can lead to formation of a deep recessed portion in the surface 12a of the plastic film 12. For example, in a polishing process which is carried out under such conditions that a particle of, for example, about 3 μm in height can be polished away, the actual height of the particle can sometimes be about 2.5 μm. In such a case, at the position of the polishing process, the surface 12s of the plastic film 12 is abraded by about 0.5 μm and, Therefore, a recessed portion of about 0.5 μm in depth can be formed. Further, in this recessed portion, a large number of minute scars (polish scars) can be formed by the polishing agent. However, the liquid material. 20a appropriately fills such a recessed portion and polish scars and, furthermore, the surface of the liquid material 20a becomes smooth due to surface tension.

After covering the surface 12s of the plastic film 12 which has various recessed portions of different sizes and minute protrusions with a layer of the liquid material 20a, the liquid material 20a is heated. As shown in FIG. 4C, by heating the liquid material 20a, the liquid material 20a once changes into gel and then can form a sintered layer 20. In the present embodiment, the step of forming the sintered layer 20 (baking step) is carried out by heating the liquid material 20a to 350° C. or higher. The heating temperature of the liquid material 20a is, for example, not less than 350′C and not more than 500° C., typically not less than 400° C., or not less than 450° C. This temperature (sintering temperature) can be set to a value close to the highest process temperature in a TFT production process which is performed later.

When the layer of the liquid material 20a changes into the sintered layer 20, the volume of the layer shrinks. It was found that the coverage by the sintered layer 20 over the underlayer is scarcely deteriorated even by volume shrinkage in the sintering.

The thickness of the thus-formed sintered layer 20 is, for example, not less than 100 nm and not more than 500 nm. When a particle of greater than 1 μm in diameter is removed by polishing, the thickness of the sintered layer 20 can be set to, for example, 200 nm or smaller. Since the sintered layer 20 has fluidity before cured, the sintered layer 20 has an upper surface flatter than the surface 12s of the underlying plastic film 12. Note that, however, in the present embodiment, the sintered layer 20 is not a simple planarization layer but moderates an abrupt change in the surface shape which is attributed to a minute protrusion 12a or recessed portion 12b such as shown in FIG. 4C and produces the important effect of preventing local performance deterioration of a gas barrier film which is to be formed on the sintered layer 20. This effect is achieved because the liquid material 20a coagulates around a protrusion 12a due to surface tension and is likely to remain in a recessed portion 12b.

In the present disclosure, the plastic film 12 and the sintered layer 20 overlying the plastic film 12 are generically referred to as “flexible supporting substrate 100”. As will be described later, by removing the glass base 11, the flexible supporting substrate 100 functions as a flexible sheet-like substrate for supporting a functional layer and a gas barrier film.

Then, as shown in FIG. 4D, a first gas barrier film 13 is formed on the sintered layer 20. The first gas barrier film 13 can have various configurations. An example of the first gas barrier film 13 is a film such as silicon oxide film or silicon nitride film. The other example of the first gas barrier film 13 can be a multilayer film including an organic material, layer and an inorganic material layer. The lower surface of the first gas barrier film 13 is defined by the upper surface of the sintered layer 20 which has high flatness. Thus, the problem of deterioration of the encapsulation performance of the first gas barrier film 13, which is attributed to various recessed portions and minute protrusions in the surface 12s of the plastic film 12, can be solved.

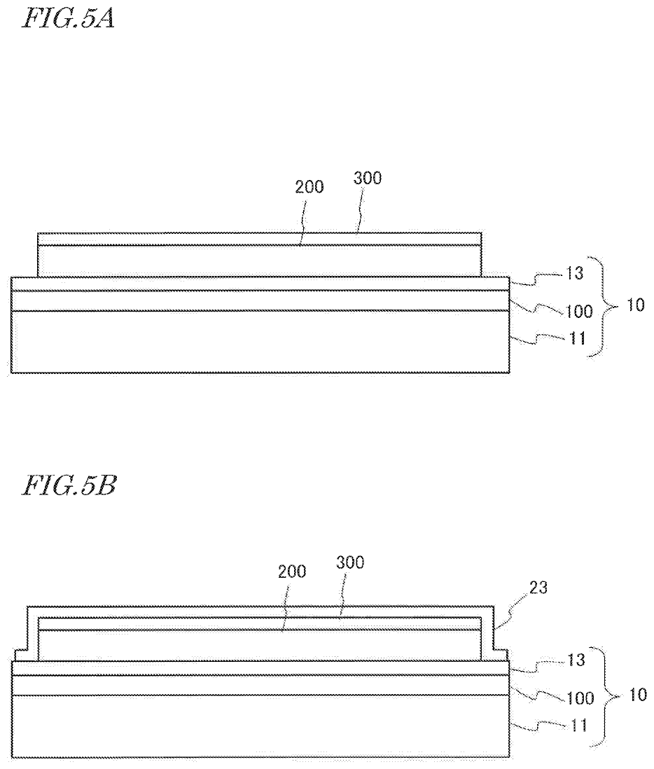

Hereinafter, the steps of forming a functional layer, which includes TFT and OLED, and a second gas barrier film are described while mainly referring to FIG. 5A through FIG. 5D.

The most characteristic feature in the present embodiment resides in the configurations of the flexible display supporting substrate and the flexible substrate and the production processes of these substrates. The descriptions of the respective processes illustrated in the following paragraphs are merely exemplary and do not limit the embodiments of the present disclosure.

First, as shown in FIG. 5A, a TFT layer 200 and an OLED layer 300 are sequentially formed on the flexible display supporting substrate 10 according to a known method. The TFT layer 200 includes a TFT array circuit which realizes an active matrix. The OLED layer 300 includes an array of OLED devices, each of which can be driven independently. The thickness of the TFT layer 200 is, for example, 4 μm. The thickness of the OLED layer is, for example, 1 μm.

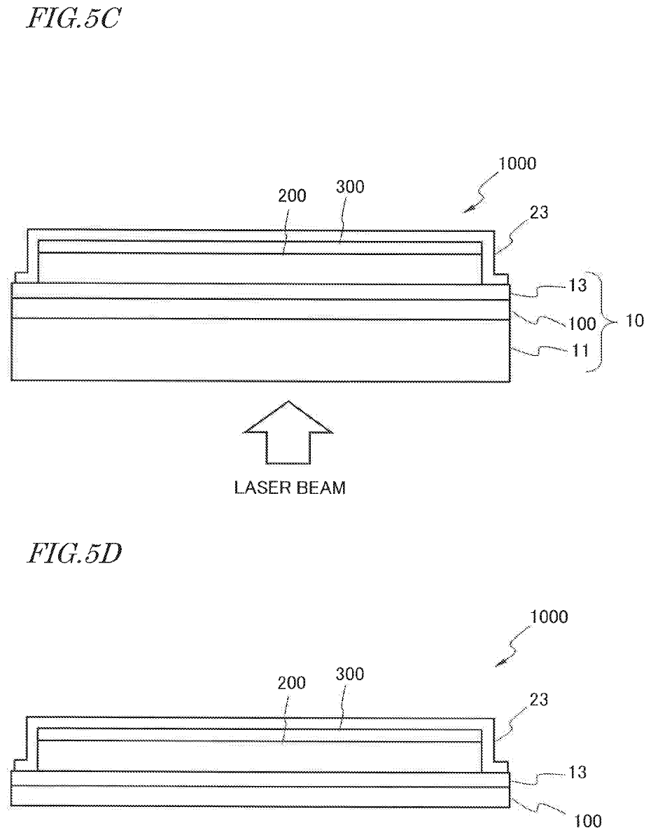

FIG. 6 is a basic equivalent circuit diagram of a sub-pixel in an organic EL (Electro Luminescence) display. A single pixel of the display can consist of sub-pixels of different colors such as, for example, R (red), G (green), and B (blue). The example illustrated in FIG. 6 includes a selection TFT element Tr1, a driving TFT element Tr2, a storage capacitor CH, and an OLED element EL. The select . . . on TFT element Tr1 is connected with a data line DL and a selection line SL. The data line DL is a line for transmitting data signals which define an image to be displayed. The data line DL is electrically coupled with the gate of the driving TFT element Tr2 via the selection TFT element Tr1. The selection line SL is a line for transmitting signals for controlling the ON/OFF state of the selection TFT element Tr1. The driving TFT element Tr2 controls the state of the electrical connection between a power line PL and the OLED element EL. When the driving TFT element Tr2 is ON, an electric current flows from the power line PL to a ground line GL via the OLED element EL. This electric current allows the OLED element EL to emit light. Even when the selection TFT element Tr1 is OFF, the storage capacitor CH maintains the ON state of the driving TFT element Tr2.

The TFT layer 200 includes a selection TFT element Tr1, a driving TFT element Tr2, a data line DL, and a selection line SL. The OLED layer 300 includes an OLED element EL. Before formation of the OLED layer 300, the upper surface of the TFT layer 200 is planarized by an interlayer insulating film that covers the TFT array and various wires. A structure which supports the OLED layer 300 and which realizes active matrix driving of the OLED layer 300 is referred to as “backplane”.

The circuit elements and part of the lines shown in FIG. 6 can be included in any of the TFT layer 200 and the OLED layer 300. The lines shown in FIG. 6 are connected with an unshown driver circuit.

In the embodiment of the present disclosure, the TFT layer 200 and the OLED layer 300 can have various specific configurations. These configurations do not limit the present disclosure. The TFT element included in the TFT layer 200 may have a bottom gate type configuration or may have a top gate type configuration. Emission by the OLED element included in the OLED layer 300 may be of a bottom emission type or may be of a top emission type. The specific configuration of the OLED element is also arbitrary.

The material of a semiconductor layer which is a constituent of the TFT element includes, for example, crystalline silicon, amorphous silicon, and oxide semiconductor. In the embodiment of the present disclosure, part of the process of forming the TFT layer 200 includes a heat treatment step at 350° C. or higher for the purpose of improving the performance of the TFT element. As previously described, in the embodiment of the present disclosure, the sintering temperature during formation of the sintered layer 20 is appropriately adjusted and, therefore, deterioration of the sintered layer 20 is suppressed or prevented in the process of forming the TFT layer 200.

After formation of the above-described functional layer, the entirety of the TFT layer 200 and the OLED layer 300 is covered with a second gas barrier film 23 as shown in FIG. 5B. A typical example of the second gas barrier film 23 is a multilayer film including an inorganic material layer and an organic material layer. Elements such as an adhesive film, another functional layer which is a constituent of a touchscreen, polarizers, etc., may be provided between the second gas barrier film 23 and the OLED layer 300. Formation of the second gas barrier film 23 can be realized by a Thin Film Encapsulation (TFE) technique. From the viewpoint of moisture resistance reliability, the WVTR (Water Vapor Transmission Rate) of a thin film encapsulation structure is typically required to be not more than 1×10⁻⁴ g/m²/day. According to the embodiment of the present disclosure, this criterion is met. The thickness of the second gas barrier film 23 is, for example, not more than 1.5 μm.

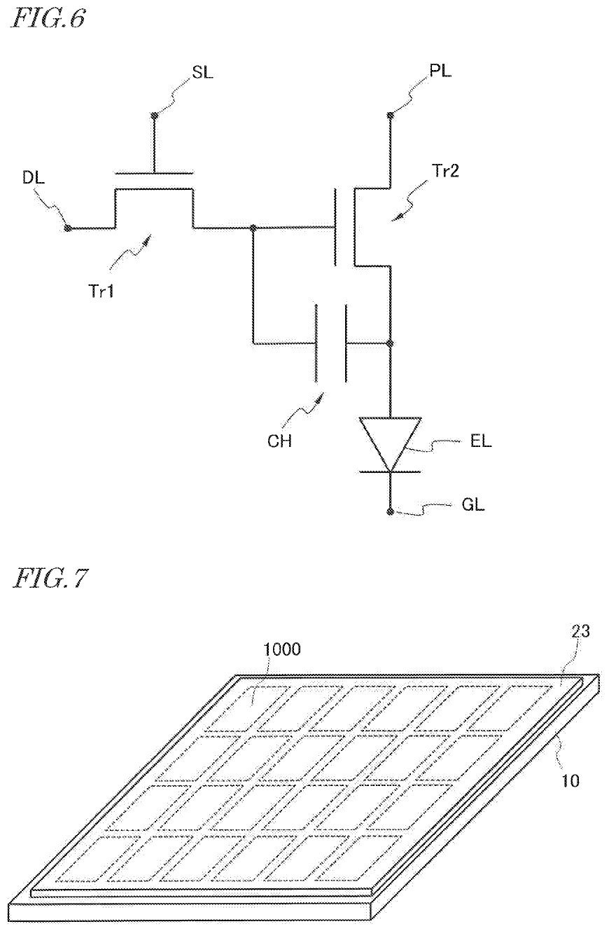

FIG. 7 is a perspective view schematically showing the upper surface side of the flexible display supporting substrate 10 at a point in time when the second gas barrier film 23 is formed. A single flexible display supporting substrate 10 supports a plurality of flexible displays 1000.

Then, as shown in FIG. 5C, the flexible supporting substrate 100 is irradiated with a laser beam from the rear surface side of the glass base 11 for lifting off. In this way, the flexible displays 1000 are obtained as shown in FIG. 5D.

According to the embodiment of the present disclosure, the moisture resistance performance of the gas barrier film on the flexible substrate side is improved so that performance deterioration of the flexible display which is attributed to entry of water vapor can be suppressed.

### INDUSTRIAL APPLICABILITY

An embodiment of the present invention is broadly applicable to smartphones, tablet computers, on-board displays, and small-, medium- and large-sized television sets.

### REFERENCE SIGNS LIST

10 . . . flexible display supporting substrate, 11 . . . glass base, 12 . . . plastic film, 12a . . . protrusion, 12b . . . recessed portion, 12s . . . surface of plastic film, 13 . . . first gas barrier film, 13c . . . crack, 20 . . . sintered layer, 20a . . . liquid material, 23 . . . second gas barrier film, 100 . . . flexible substrate, 200 . . . TFT layer, 300 . . . OLED layer, 1000 . . . flexible display

1. A flexible display comprising:
a flexible substrate;
an OLED device supported by the flexible substrate;
a first gas barrier film covering the flexible substrate, the first gas barrier film being located between the OLED device and the flexible substrate; and
a second gas barrier film supported by the flexible substrate and covering the OLED device,
wherein the flexible substrate includes
a plastic film which has a front surface and a rear surface flatter than the front surface, and
a sintered layer covering the front surface of the plastic film,
wherein the front surface of the plastic film has polishing scars including a protrusion whose height is not less than 50 nm and not more than 300 nm and/or a recessed portion whose depth is not less than 50 nm and not more than 300 nm,
the sintered layer is made of an oxide of one or more metal elements selected from the group consisting of Ti, Ta and Al,
the thickness of the sintered layer is not less than 100 nm and not more than 500 nm, the sintered layer planarizing the polishing scars on the front surface of the plastic and having an upper surface flatter than the front surface of the plastic film.

2-4. (canceled)

5. The flexible display of claim 1, wherein the plastic film is made of biphenyl type polyimide.

6. A flexible display supporting substrate comprising:
a glass base;
a plastic film which has a surface, the plastic film being supported by the glass base;
a sintered layer covering the surface of the plastic film, and
a gas barrier film covering the sintered layer,
wherein the front surface of the plastic film has polishing scars including a protrusion whose height is not less than 50 nm and not more than 300 nm and/or a recessed portion whose depth is not less than 50 nm and not more than 300 nm,
the sintered layer is made of an oxide of one or more metal elements selected from the group consisting of Ti, Ta and Al,
the thickness of the sintered layer is not less than 100 nm and not more than 500 nm, the sintered layer planarizing the polishing scars on the front surface of the plastic and having an upper surface flatter than the front surface of the plastic film.

7-8. (canceled)

9. A flexible display production method comprising:
providing a flexible display supporting substrate which includes a glass base and a plastic film on the glass base;
polishing a part of the front surface of the plastic film, thereby forming polishing scars including a protrusion whose height is not less than 50 nm and not more than 300 nm and/or a recessed portion whose depth is not less than 50 nm and not more than 300 nm on the part of the front surface of the plastic film,
forming a sintered layer so as to cover a surface of the plastic film;
forming a first gas barrier film so as to cover a surface of the sintered layer;
forming an OLED device so as to be supported by the flexible substrate; and
forming a second gas barrier film so as to be supported by the flexible substrate and so as to cover the OLED device,
wherein forming the sintered layer includes:
supplying a liquid material to the front surface of the plastic film,
forming the sintered layer of the liquid material by heating the liquid material to 450° C. or higher, the liquid material is a sol which contains an alkoxide of one or more metal elements selected from the group consisting of Ti, Ta and Al.

10-14. (canceled)

15. The method of claim 9, wherein
the plastic film is made of polyimide, and
the pH of the liquid material is not more than 10.
